(19) United States
(12) Patent Application Publication
(10) Pub. No.: US 2025/0364455 A1
(43) Pub. Date: Nov. 27, 2025

(54) SUBSTRATE

(71) Applicant: CHIPBOND TECHNOLOGY CORPORATION, Hsinchu (TW)

(72) Inventor: Shih-Chieh Chang, Chiayi County (TW)

(21) Appl. No.: 19/027,079

(22) Filed: Jan. 17, 2025

(30) Foreign Application Priority Data
May 27, 2024 (TW) 113119587

(51) Int. Cl. H01L 23/00

(52) U.S. Cl. CPC H01L 24/05; H01L 2224/0225; H01L 2224/05558

(57) ABSTRACT

A substrate includes a body, at least one guiding bump and a metal layer. The guiding bump is provided on the body and includes a first guiding bar and a second guiding bar, the first guiding bar has a first curved end and a first curved inner surface, and the second guiding bar has a second curved end and a second curved inner surface. The metal layer is provided in a guiding groove between the first and second curved inner surfaces. The first and second curved inner surfaces are covered by a first and second curved guiding elements of the metal layer, respectively. The width of a bonding groove between the first and second curved guiding elements is increased gradually in a direction from the body to an opening of the guiding groove.

### CROSS-REFERENCE TO RELATED APPLICATIONS

This application claims priority to R.O.C Patent Application No. 113119587 filed May 27, 2024, the disclosure of which is hereby incorporated by reference in its entirety.

### FIELD OF THE INVENTION

This invention relates to a substrate having guiding bump(s), which is able to be bonded with lead, metal pillar or conductive bump of another substrate by the guiding bump(s).

### BACKGROUND OF THE INVENTION

Due to bump pitch minimization, it is not easy to align leads or metal pillars to bumps with fine pitch. If the leads or metal pillars are dislocated, they may be bonded to bumps obliquely or bonded to unexpected bumps. Otherwise, ion migration, metal migration or electromigration may occur between the adjacent bumps with fine pitch to bridge the adjacent bumps and lower electrical efficiency or yield.

### SUMMARY OF THE INVENTION

One object of the present invention is to provide a substrate having guiding bump(s). When a bonding element, e.g., lead, metal pillar or conductive bump, is bonded to the substrate of the present invention, the substrate can guide the bonding element into a bonding groove of a metal layer on a bump to prevent electrical disconnection of the bonding element and the metal layer, prevent the bonding element from being bonded to the metal layer obliquely or prevent the bonding element from being bonded to another unexpected bump.

A substrate of the present invention includes a body, at least one guiding bump and a metal layer. The guiding bump is provided on the body and includes a first guiding bar and a second guiding bar which are located at both sides of a conductive pad on the body, respectively. The first guiding bar has a first curved end, a first curved inner surface and a first outer surface. The first curved inner surface extends from the body to the first curved end and is connected to the first curved end. A first width of the first guiding bar, which is between the first curved inner surface and the first outer surface along a first direction parallel to the body, is reduced gradually in a direction from the body to the first curved end. The second guiding bar has a second curved end, a second curved inner surface and a second outer surface. The second curved inner surface extends from the body to the second curved end and is connected to the second curved end. A second width of the second guiding bar, which is between the second curved inner surface and the second outer surface along the first direction, is reduced gradually in a direction from the body to the second curved end. The first curved inner surface faces toward the second curved inner surface, there is a guiding groove between the first and second curved inner surfaces, and the conductive pad is visible from the guiding groove. A third width of the guiding groove, which is between the first and second curved inner surfaces along the first direction, is increased gradually in a direction from the body to an opening of the guiding groove. The metal layer is provided in the guiding groove and electrically connected to the conductive pad. The metal layer has a first curved guiding element and a second curved guiding element, the first and second curved inner surfaces are covered by the first and second curved guiding elements, respectively, and the first and second outer surfaces are not covered by the metal layer. A bonding groove existing between the first and second curved guiding elements is provided to be bonded to a bonding element on another substrate. A fourth width of the bonding groove, which is between the first and second curved guiding elements along the first direction, is increased gradually in the direction from the body to the opening of the guiding groove.

The dislocated bonding element can be guided by the first or second curved guiding element to enter the bonding groove to be electrically connected to the metal layer, so the present invention can prevent the bonding element from being not electrically connected to the metal layer, prevent the bonding element from being bonded to the metal layer obliquely or prevent the bonding element from being bonded to another bump next to the corresponding bump. Furthermore, the metal layer does not cover the first and second outer surfaces of the first and second guiding bars, it is designed to be located between the first and second curved inner surfaces of the first and second guiding bars, thereby avoiding bridge between the metal layers on the adjacent guiding bumps induced by ion migration, metal migration or electromigration.

### BRIEF DESCRIPTION OF DRAWINGS

FIG. 1 is a top view diagram illustrating a substrate in accordance with a first embodiment of the present invention.

FIG. 2 is a top view diagram illustrating a guiding bump and a metal layer of a substrate in accordance with a first embodiment of the present invention.

FIG. 3 is a cross-section view diagram illustrating a substrate in accordance with a first embodiment of the present invention.

FIGS. 4 and 5 are cross-section view diagrams illustrating a substrate and another substrate in accordance with a first embodiment of the present invention.

FIGS. 6 and 7 are top view diagrams illustrating guiding bumps and metal layers bonded to bonding elements of another substrate in accordance with a first embodiment of the present invention.

FIG. 8 is a cross-section view diagram illustrating a substrate and a test probe in accordance with a first embodiment of the present invention.

FIG. 9 is a top view diagram illustrating a guiding bump and a metal layer of a substrate in accordance with a second embodiment of the present invention.

FIG. 10 is a top view diagram illustrating a guiding bump and a metal layer bonded to a bonding element of another substrate in accordance with a second embodiment of the present invention.

FIG. 11 is a cross-section view diagram illustrating a guiding bump and a metal layer bonded to a bonding element of another substrate in accordance with a second embodiment of the present invention.

FIG. 12 is a top view diagram illustrating a guiding bump and a metal layer of a substrate in accordance with a third embodiment of the present invention.

### DETAILED DESCRIPTION OF THE INVENTION

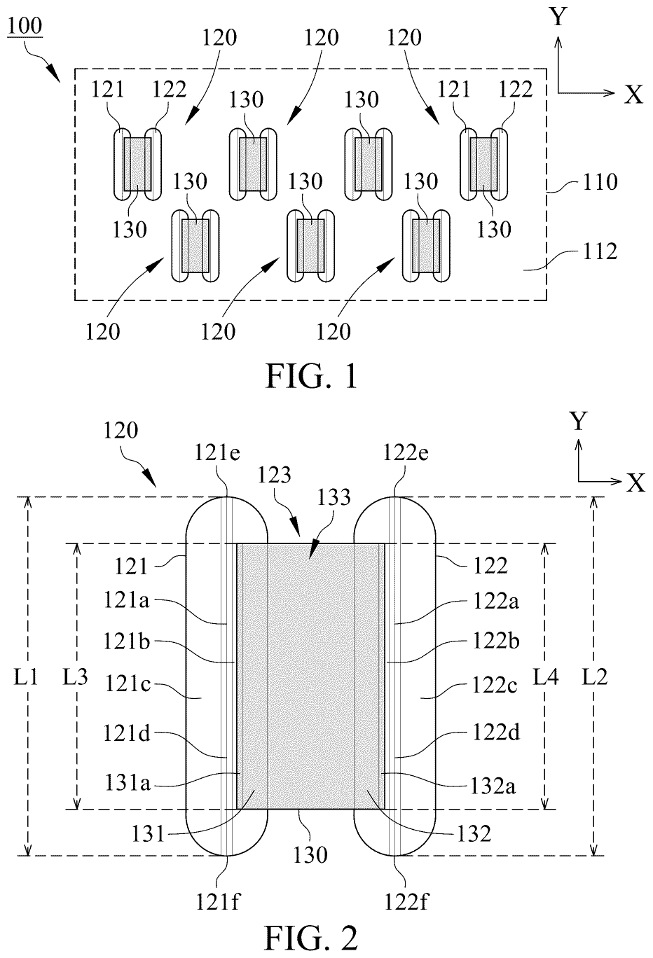

FIGS. 1 to 8 are diagrams provided to illustrate a first embodiment of the present invention. With reference to FIGS. 1 to 3, a substrate 100 includes a body 110, at least one guiding bump 120 and a metal layer 130. The body 110 is, but not limited to, a chip having at least one conductive pad 111. In this embodiment, the body 110 further has a protective layer 112 which exposes the conductive pad 111.

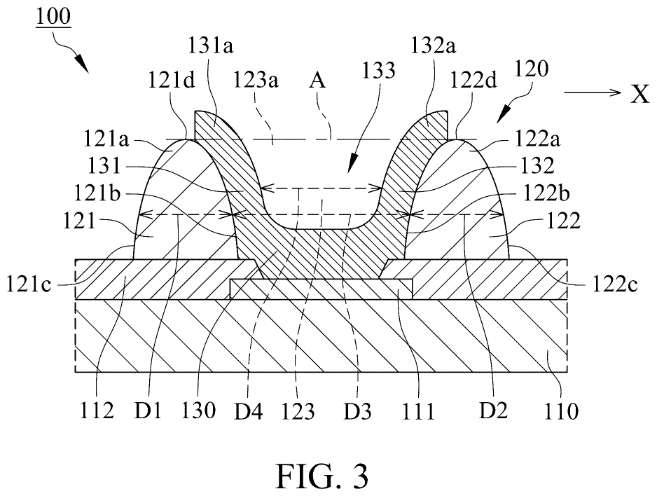

With reference to FIGS. 2 and 3, the guiding bump 120 is provided on the body 110 and it can be made of polymer material, e.g., polyimide (PI). The guiding bump 120 is arranged on the protective layer 112 in this embodiment. The guiding bump 120 includes a first guiding bar 121 and a second guiding bar 122 which are located on both sides of the conductive pad 111, respectively. In this embodiment, the first guiding bar 121 is parallel to the second guiding bar 122.

With reference to FIG. 3, the first guiding bar 121 has a first curved end 121a, a first curved inner surface 121b and a first outer surface 121c, and the second guiding bar 122 has a second curved end 122a, a second curved inner surface 122b and a second outer surface 122c. The first curved inner surface 121b extends from the body 110 to the first curved end 121a and is connected to the first curved end 121b, and the second curved inner surface 122b extends from the body 110 to the second curved end 122a and is connected to the second curved end 122a. The first curved inner surface 121b faces toward the second curved inner surface 122b, there is a guiding groove 123 between the first and second curved inner surfaces 121b and 122b, and the conductive pad 111 is visible from the guiding groove 123.

With reference to FIGS. 2 and 3, along a first direction X parallel to the body 110, there is a first width D1 between the first curved inner surface 121b and the first outer surface 121c, and there is a second width D2 between the second curved inner surface 122b and the second outer surface 122c. The first width D1 of the first guiding bar 121 is reduced gradually in a direction from the body 110 to the first curved end 121a, and the second width D2 of the second guiding bar 122 is reduced gradually in a direction from the body 110 to the second curved end 122a. There is a third width D3 between the first and second curved inner surfaces 121b and 122b along the first direction X, and the third width D3 of the guiding groove 123 is increased gradually in a direction from the body 110 to an opening 123a of the guiding groove 123.

With reference to FIGS. 2 and 3, the metal layer 130 is provided in the guiding groove 123 and electrically connected to the conductive pad 111, and it can be made of metal, such as gold, or alloy. The metal layer 130 includes a first curved guiding element 131 and a second curved guiding element 132, the first curved guiding element 131 covers the first curved inner surface 121b of the first guiding bar 121, and the second curved guiding element 132 covers the second curved inner surface 122b of the second guiding bar 122. The metal layer 130 does not cover the first outer surface 121c of the first guiding bar 121 and the second outer surface 122c of the second guiding bar 122. In this embodiment, the first curved guiding element 131 is parallel to the second curved guiding element 132. A bonding groove 133 exists between the first and second curved guiding elements 131 and 132, there is a fourth width D4 between the first and second curved guiding elements 131 and 132 along the first direction X, and the fourth width D4 of the bonding groove 133 is increased gradually in the direction from the body 110 to the opening 123a of the guiding groove 123.

With reference to FIG. 2, along a second direction Y intersecting the first direction X, a first length L1 of the first curved inner surface 121b of the first guiding bar 121 is longer than a third length L3 of the first curved guiding element 131 of the metal layer 130, and a second length L2 of the second curved inner surface 122b of the second guiding bar 122 is longer than a fourth length L4 of the second curved guiding element 132 of the metal layer 130.

With reference to FIG. 2, in this embodiment, the first curved guiding element 131 of the metal layer 130 does not cover a first terminal 121e of the first guiding bar 121, and the second curved guiding element 132 of the metal layer 130 does not cover a third terminal 122e of the second guiding bar 122. Preferably, the first curved guiding element 131 of the metal layer 130 also does not cover a second terminal 121f of the first guiding bar 121, and the second curved guiding element 132 of the metal layer 130 also does not cover a fourth terminal 122f of the second guiding bar 122.

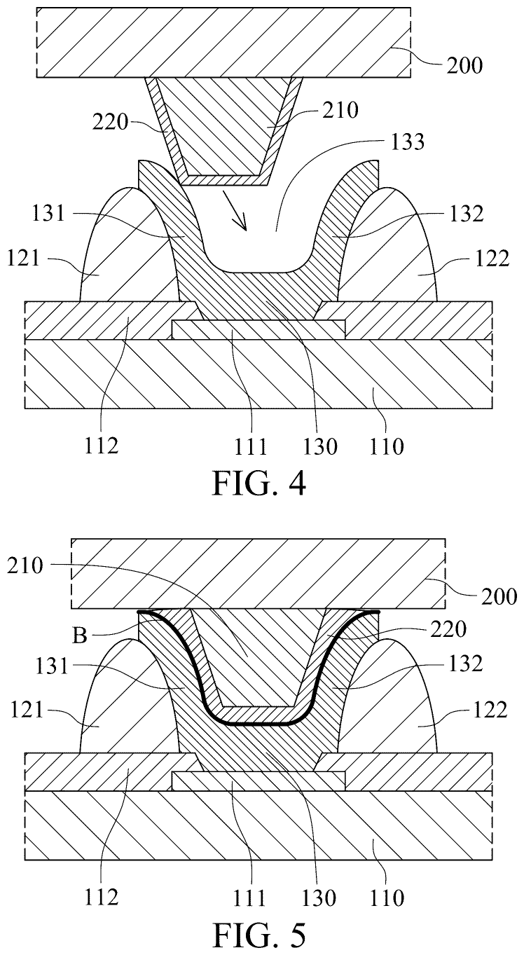

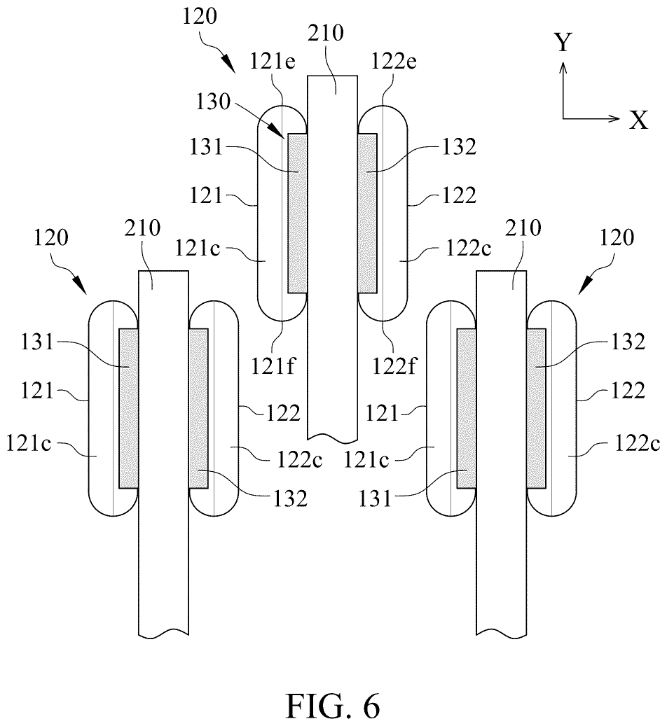

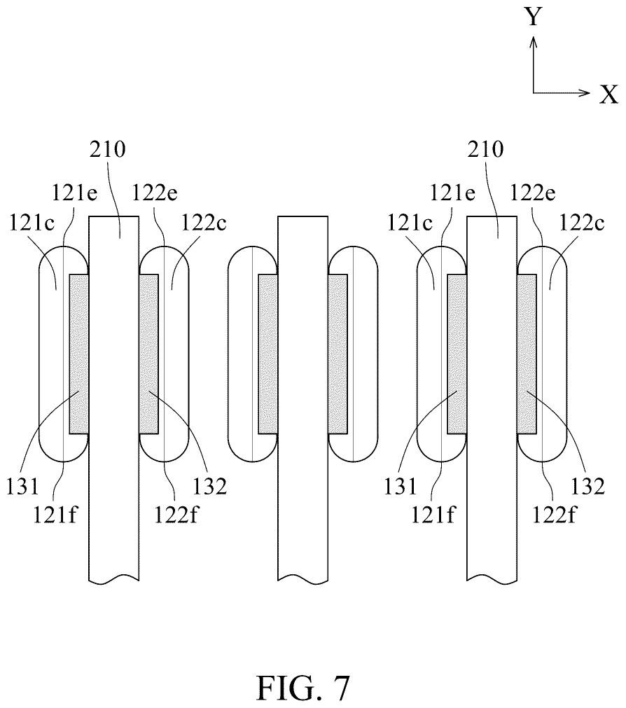

With reference to FIGS. 4 and 5, when another substrate 200 is moved to allow its bonding element 210, such as lead, metal pillar or conductive bump, to be bonded to the substrate 100 but the bonding element 210 is dislocated and unable to align the bonding groove 133 correctly, the dislocated bonding element 210 can be guided to move into the bonding groove 133 by the first curved guiding element 131 or the second curved guiding element 132 to be electrically connected to the metal layer 130. As shown in FIGS. 6 and 7, the dislocated bonding element 210 will not be electrically connected to the unexpected metal layer 130 on the adjacent guiding bump 120 owing to the first and second outer surfaces 121c and 122c are not covered by the metal layer 130.

With reference to FIGS. 4 and 5, when the bonding element 210 contacts the first and second curved guiding elements 131 and 132, the shear stress applied on the first and second curved guiding elements 131 and 132 by the bonding element 210 can be reduced because of the curved surfaces of the first and second curved guiding elements 131 and 132. The first width D1 of the first guiding bar 121 is reduced gradually in the direction from the body 110 to the first curved end 121a and the second width D2 of the second guiding bar 122 is reduced gradually in the direction from the body 110 to the second curved end 122a, thus, the first and second curved guiding elements 131 and 132 will not be pushed laterally by the shear stress to be peeled from the body 110.

With reference to FIGS. 2, 5, 6 and 7, the metal layer 130 is formed between the first and second curved inner surfaces 121b and 122b, it does not cover the first outer surface 121c, the first and second terminals 121e and 121f of the first guiding bar 121 and not cover the second outer surface 122c, the third and fourth terminals 122e and 122f of the second guiding bar 122. The area of the metal layer 130 can be reduced so the metal layers 130 on the adjacent guiding bumps 120 will not be bridged caused by ion migration, metal migration or electromigration while the bonding element 210 on the substrate 200 is bonded to the metal layer 130.

With reference to FIG. 5, owing to the metal layer 130 does not cover the first outer surface 121c, the first and second terminals 121e and 121f of the first guiding bar 121 and not cover the second outer surface 122c, the third and fourth terminals 122e and 122f of the second guiding bar 122, the covering area of a filling material provided between the substrates 100 and 200 can be increased to enhance the bonding strength of the substrates 100 and 200. Preferably, the first and second outer surfaces 121c and 122c are curved surfaces. In this embodiment, the bonding element 210 is made of copper (Cu) and a bonding layer 220 made of tin (Sn) is provided on the bonding element 210. Due to the metal layer 130 is provided in the guiding groove 123, the thickness of the first and second curved guiding elements 131 and 132 can be increased to lower the thickness of an intermetallic compound (IMC) B generated between the bonding element 210 and the metal layer 130.

With reference to FIGS. 2, 3 and 5, an imaginary line A passes through a first top 121d of the first curved end 121a and a second top 122d of the second curved end 122a. A first curved bonding portion 131a of the first curved guiding element 131 and a second curved bonding portion 132a of the second curved guiding element 132 are higher than the imaginary line A. In this embodiment, the first top 121d of the first curved end 121a is not covered by the first curved bonding portion 131a, the second top 122d of the second curved end 122a is not covered by the second curved bonding portion 132a, and the first and second curved bonding portions 131a and 132a are higher than the first and second curved ends 121a and 122a. After bonding the bonding element 210 of the substrate 200 to the metal layer 130 in the guiding groove 123, only the first and second curved bonding portions 131a and 132a are exposed, so ion migration, metal migration or electromigration will not happen to cause bridge between the metal layers 130 on the adjacent guiding bumps 120.

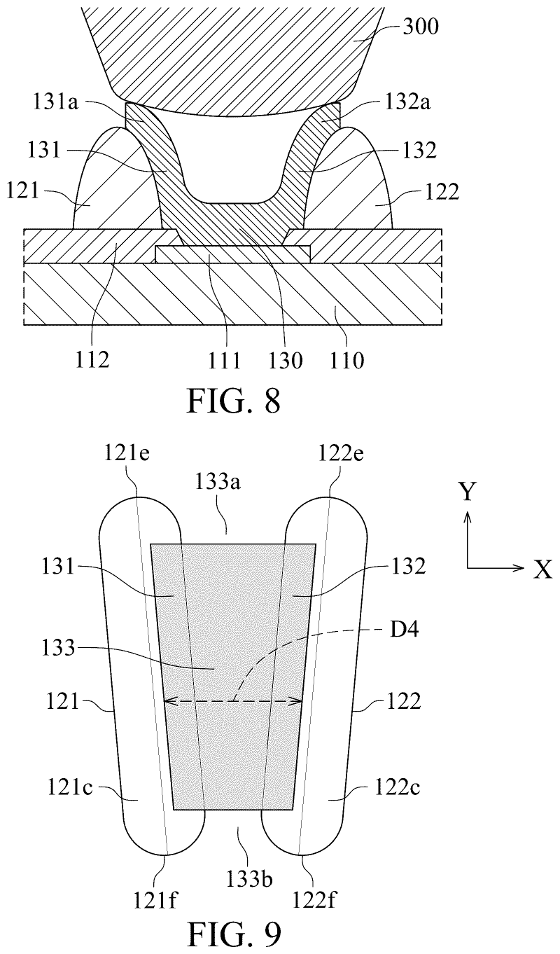

With reference to FIGS. 3 and 8, when the guiding bump 120 is tested using a test probe 300, the test probe 300 can contact the first and second curved bonding portions 131a and 132a which are higher than the imaginary line A, and the test probe 300 can be guided by the first and second curved bonding portions 131a and 132a to prevent the test probe 300 from shifting and being unable to contact the metal layer 130.

A second embodiment of the present invention is illustrated in FIGS. 9 to 11. With reference to FIG. 9, different to the first embodiment, the first and second guiding bars 121 and 122 are not parallel to each other in the second embodiment. The bonding groove 133 has a front end 133a and a back end 133b along the second direction Y, and the fourth width D4 between the first and curved guiding elements 131 and 132 is reduced gradually in a direction from the front end 133a to the back end 133b.

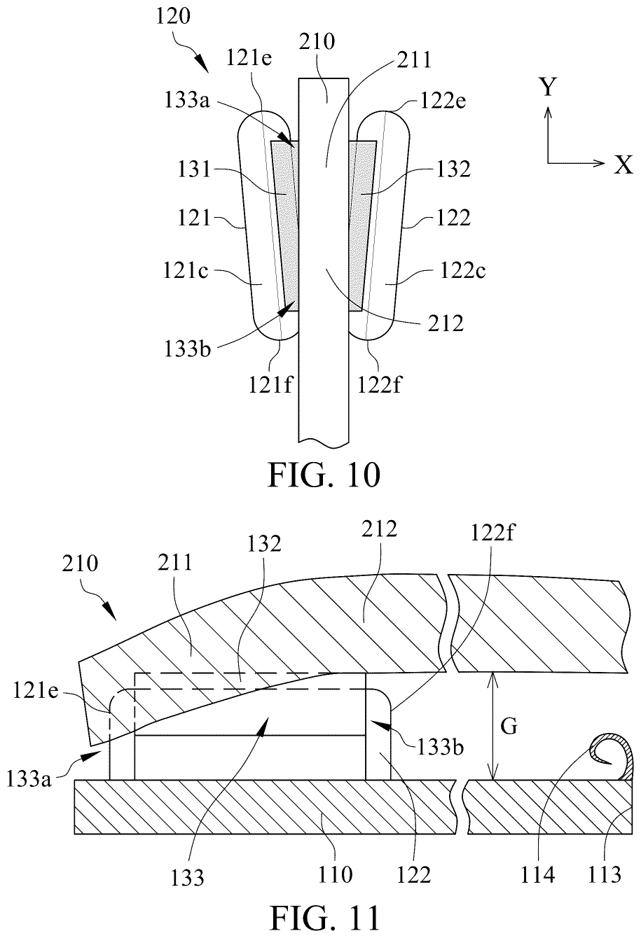

With reference to FIGS. 10 and 11, when the substrate 200 is moved to allow the bonding element 210 to into the bonding groove 133 and be bonded to the first and second curved guiding elements 131 and 132, the first and second curved guiding elements 131 and 132 located at both sides of the front end 133a are provided to guide a first bonding portion 211 of the bonding element 210, and the first and second curved guiding elements 131 and 132 located at both sides of the back end 133b are provided to support a second bonding portion 212 of the bonding element 210. Consequently, the bonding element 210 is located in the bonding groove 133 obliquely to bond with the metal layer 130. A gap G between the bonding element 210 and the body 110 is increased gradually in the direction from the front end 133a to the back end 133b, and the back end 133b will not contact a metal burr 114 located on an edge 113 of the body 110 to cause short circuiting or electrical abnormality.

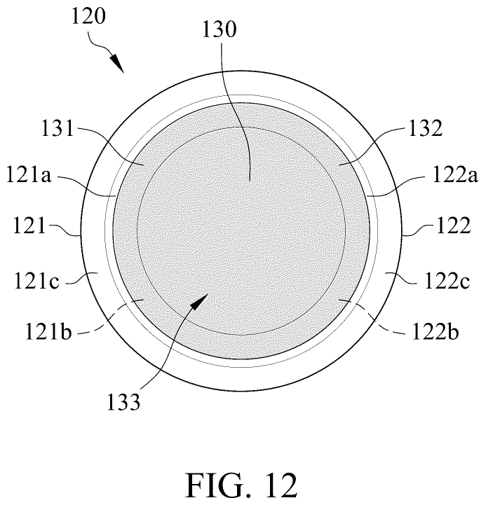

In a third embodiment of the present invention as shown in FIG. 12, the first and second guiding bars 121 and 122 are connected to each other to become a circular guiding bar, the first and second curved guiding elements 131 and 132 are connected to each other and the metal layer 130 is dish-shape.

While this invention has been particularly illustrated and described in detail with respect to the preferred embodiments thereof, it will be clearly understood by those skilled in the art that is not limited to the specific features shown and described and various modified and changes in form and details may be made without departing from the scope of the claims.

1. A substrate comprising:
a body including at least one conductive pad;
at least one guiding bump provided on the body and including a first guiding bar and a second guiding bar, the first guiding bar is located on one side of the at least one conductive pad and the second guiding bar is located on the other side of the at least one conductive pad, the first guiding bar has a first curved end, a first curved inner surface and a first outer surface, the first curved inner surface extends in a direction from the body to the first curved end and is connected to the first curved end, a first width between the first curved inner surface and the first outer surface along a first direction parallel to the body is reduced gradually in the direction from the body to the first curved end, the second guiding bar has a second curved end, a second curved inner surface and a second outer surface, the second curved inner surface extends in a direction from the body to the second curved end and is connected to the second curved end, a second width between the second curved inner surface and the second outer surface along the first direction is reduced gradually in the direction from the body to the second curved end, the first curved inner surface faces toward the second curved inner surface and there is a guiding groove between the first and second curved inner surfaces, the at least one conductive pad is visible from the guiding groove, and a third width between the first and second curved inner surfaces along the first direction is increased gradually in a direction from the body to an opening of the guiding groove; and
a metal layer provided in the guiding groove and electrically connected to the at least one conductive pad, the metal layer includes a first curved guiding element and a second curved guiding element, the first curved inner surface of the first guiding bar is covered by the first curved guiding element, the second curved inner surface of the second guiding bar is covered by the second curved guiding element, and the first outer surface of the first guiding bar and the second outer surface of the second guiding bar are not covered by the meal layer, a bonding groove formed between the first and second curved guiding elements is provided for bonding with a bonding element, and a fourth width between the first and second curved guiding elements along the first direction is increased gradually in the direction from the body to the opening of the guiding groove.

2. The substrate in accordance with claim 1, wherein a first top of the first curved end and a second top of the second curved end are passed by an imaginary line, and a first curved bonding portion of the first curved guiding element and a second curved bonding portion of the second curved guiding element are higher than the imaginary line.

3. The substrate in accordance with claim 2, wherein the first top of the first curved end is not covered by the first curved bonding portion of the first curved guiding element.

4. The substrate in accordance with claim 3, wherein the second top of the second curved end is not covered by the second curved bonding portion of the second curved guiding element.

5. The substrate in accordance with claim 1, wherein a first length of the first curved inner surface of the first guiding bar is longer than a third length of the first curved guiding element of the metal layer in a second direction intersecting the first direction.

6. The substrate in accordance with claim 5, wherein the first guiding bar further has a first terminal and a second terminal along the second direction, and the first terminal is not covered by the first curved guiding element.

7. The substrate in accordance with claim 6, wherein the second terminal is not covered by the first curved guiding element.

8. The substrate in accordance with claim 6, wherein a second length of the second curved inner surface of the second guiding bar is longer than a fourth length of the second curved guiding element of the metal layer in the second direction.

9. The substrate in accordance with claim 8, wherein the second guiding bar further has a third terminal and a fourth terminal along the second direction, and the third terminal is not covered by the second curved guiding element.

10. The substrate in accordance with claim 9, wherein the fourth terminal is not covered by the second curved guiding element.

11. The substrate in accordance with claim 8, wherein the first and second curved guiding elements are parallel.

12. The substrate in accordance with claim 11, wherein the first and second guiding bars are parallel.

13. The substrate in accordance with claim 1, wherein the bonding groove has a front end and a back end in a second direction intersecting the first direction, the fourth width of the bonding groove is reduced gradually in a direction from the front end to the back end.

14. The substrate in accordance with claim 13, wherein the first and second guiding bars are not parallel.

15. The substrate in accordance with claim 1, wherein the first and second guiding bars are connected to each other to become a circular guiding bar, the first and second curved guiding elements are connected to each other and the metal layer is dish-shape.

16. The substrate in accordance with claim 1, wherein the first outer surface of the first guiding bar is a curved surface.

17. The substrate in accordance with claim 16, wherein the second outer surface of the second guiding bar is a curved surface.
